(19) United States
(12) Patent Application Publication
(10) Pub. No.: US 2014/0102766 A1
(43) Pub. Date: Apr. 17, 2014

(54) MULTI-LAYER TYPE CORELESS SUBSTRATE AND METHOD OF MANUFACTURING THE SAME

(71) Applicant: SAMSUNG ELECTRO-MECHANICS CO., LTD., Suwon (KR)

(72) Inventors: Da Hee Kim, Suwon (KR); Yoong Oh, Suwon (KR); Ki Young Yoo, Suwon (KR); Han Ul Lee, Suwon (KR); Myung Sam Kang, Suwon (KR); Ki Hwan Kim, Suwon (KR)

(73) Assignee: SAMSUNG ELECTRO-MECHANICS CO., LTD., Suwon (KR)

(21) Appl. No.: 13/831,534

(22) Filed: Mar. 14, 2013

(30) Foreign Application Priority Data
Oct. 15, 2012 (KR) 10-2012-0114390

(51) Int. Cl. H05K 3/46; H05K 1/02

(52) U.S. Cl. CPC H05K 3/46; H05K 1/0298
USPC 174/251; 29/846

(57) ABSTRACT

Disclosed herein is a multi-layer type coreless substrate, including: a first insulating layer including at least one first pillar; a plurality of insulating layers laminated on one surface or both surfaces of the first insulating layer, each including at least one circuit layer and at least another pillar connected to the circuit layer; and a plurality of outermost circuit layers contacting a pillar disposed on an outermost insulating layer of the plurality of insulating layers.

### CROSS REFERENCE TO RELATED APPLICATION

This application claims the benefit of Korean Patent Application No. 10-2012-0114390, filed on Oct. 15, 2012, entitled “Multi-Layer Type Coreless Substrate and Method of Manufacturing the Same”, which is hereby incorporated by reference in its entirety into this application.

### BACKGROUND OF THE INVENTION

1. Technical Field

The present invention relates to a multi-layer type coreless substrate and a method of manufacturing the same.

2. Description of the Related Art

Generally, a printed circuit board is implemented by wiring a copper foil on one surface or both surfaces of a board made of various kinds of thermosetting synthetic resins, fixing IC or electronic components on the board, and implementing electrical wirings therebetween and then, coating the electrical wirings with an insulator.

Recently, with the development of electronic industries, a demand for multi-functional and light and small electronic components has been rapidly increased. Accordingly, there is a need to increase a wiring density of a printed circuit board on which the electronic components are mounted and reduce a thickness thereof.

In particular, in order to cope with the thinness of the printed circuit board, a coreless substrate with the reduced thickness and signal processing time by removing a core substrate has been spotlighted. In case of the coreless substrate, since the core substrate is removed, a carrier member serving as a support during a manufacturing process is required.

An upper substrate and a lower substrate are separated from each other by forming a buildup layer including circuit layers and insulating layers on both surfaces of the carrier member according to a method of manufacturing a substrate of the prior art and removing the carrier member, such that the coreless substrate is completed.

As described in Patent Document 1, the method of manufacturing a coreless substrate of the prior art performs a laser direct ablation (LDA) method of forming opening parts on an insulating layer as a previous stage for forming vias for electrical connection of each buildup layer.

However, the LDA method may cause an increase in machining time due to a limitation of a laser spot size when a size of the opening part is large.

Further, the method of manufacturing a coreless substrate according to the prior art need to perform laser machining several times, thereby increasing complexity and costs of process.

### PRIOR ART DOCUMENT

### Patent Document

(Patent Document 1) Korean Patent Laid-Open Publication No. 2010-0043547 (laid-open published on Apr. 29, 2010)

### SUMMARY OF THE INVENTION

The present invention has been made in an effort to provide a multi-layer type coreless substrate on which a plurality of pillars for electrically connecting buildup layers using a dry film are formed.

Further, the present invention has been made in an effort to provide a method of manufacturing a multi-layer type coreless substrate on which a plurality of pillars for electrically connecting buildup layers using a dry film are formed.

According to a preferred embodiment of the present invention, there is provided a multi-layer type coreless substrate, including: a first insulating layer including at least one first pillar; a plurality of insulating layers laminated on one surface or both surfaces of the first insulating layer, each including at least one circuit layer and at least another pillar connected to the circuit layer; and a plurality of outermost circuit layers contacting a pillar disposed on an outermost insulating layer of the plurality of insulating layers.

The circuit layers may symmetrically contact each other on both surfaces thereof, based on the first pillar and the pillars each connected with the circuit layers symmetrically contacting each other may be symmetrically provided based on the first pillar.

The outermost circuit layer may be provided with a first surface treating film or a second surface treating layer.

The circuit layers and other pillars may be sequentially disposed repeatedly, by including the circuit layer contacting the first pillar and the pillar connected to the circuit layer.

The first surface treating film may be formed of any one of an organic solderability preservative (OSP) treating film, a black oxide film, and a brown oxide film, instead of a solder resist (SR).

The second surface treating film may be formed of any one of a gold plating film, an electrolytic gold plating film, an electroless gold plating film, and an electroless nickel immersion gold (ENIG) film.

According to an another preferred embodiment of the present invention, there is provided a method of manufacturing a multi-layer type coreless substrate, including: (A) preparing a carrier substrate including an insulating plate having at least one copper foil disposed on one surface or both surfaces thereof; (B) forming a plurality of first pillars on one surface or both surfaces of the carrier substrate using a first dry film pattern; (C) thermo-compressing a first compression layer sequentially including a first insulating layer and a first metal foil to one surface or both surfaces of the carrier substrate; (D) removing a protruded portion of the first metal foil and forming a circuit layer on an outer surface of a first insulating layer on which the first pillar is exposed; (E) forming a plurality of second pillars connected with the circuit layer using a second dry film pattern disposed on the outer surface of the first insulating layer; (F) thermo-compressing a second compression layer sequentially including a second insulating layer and a second metal foil to the outer surface of the first insulating layer on which the second pillar is disposed; (E) separating the carrier substrate; and (H) removing a protruded portion of the second metal foil and laminating a plurality of other insulating layers on which other circuit layers and other pillars are sequentially disposed on an outer surface of the second insulating layer on which the second pillar is exposed or the outer surface of the first insulating layer on which the first pillar is exposed.

The method of manufacturing a multi-layer type coreless substrate may further include: (I) forming an outermost circuit layer on an outermost insulating layer of the other insulating layers; and (J) forming a first surface treating film or a second surface treating film on the outermost circuit layer.

The step (B) may include: (B-1) forming a seed layer on one surface or both surfaces of the carrier substrate; (B-2) forming the first dry film pattern on the seed layer; (B-3) plating copper on the first dry film pattern by a chemical copper plating method; and (B-4) peeling off the first dry film pattern.

In the step (C), the first insulating layer in a non-cured state may be thermo-compressed to the first pillar using a thermo-compression jig.

In the step (C), a height t of the first pillar may be formed in a range of 1.1 to 2.0 times as much as a thickness T of the first insulating layer.

The step (D) may include: (D-1) performing a partial polishing process for removing a protruded portion of the first metal foil; (D-2) forming a seed layer on the outer surface of the first insulating layer on which the first pillar is exposed; and (D-3) forming the circuit layer by performing any one of an additive method using chemical copper plating, a semi-additive process (SAP) and a modified semi-additive process (MSAP) on the seed layer.

In the step (D-1), the partial polishing process may use an end-mill.

The step (E) may include: (E-1) forming a seed layer on the outer surface of the first insulating layer; (E-2) forming a second dry film pattern on the seed layer; (E-3) plating copper on the second dry film pattern by a chemical copper plating method to form the second pillar; and (E-4) peeling off the second dry film pattern.

In the step (F), the second insulating layer in a non-cured state may be thermo-compressed to the second pillar using a thermo-compression jig.

The step (H) may include: (H-1) performing a partial polishing process for removing a protruded portion of the second metal foil; (H-2) forming another seed layer on the outer surface of the second insulating layer on which the second pillar is exposed or the outer surface of the first insulating layer on which the first pillar is exposed; (H-3) forming the other circuit layers by performing any one of an additive method using chemical copper plating, a semi-additive process (SAP) and a modified semi-additive process (MSAP) on another seed layer; (H-4) forming other dry film patterns on the other circuit layers; (H-5) plating copper on the other dry film patterns by a chemical copper plating method to form the plurality of other pillars connected with the other circuit layers; (H-6) peeling off the other dry film patterns; and (H-7) thermo-compressing other compression layers on which the other insulating layers and the other metal foils are sequentially disposed to other seed layers including the other pillars, wherein the steps (H-1) to (H-7) are repeatedly performed.

According to still preferred embodiment of the present invention, there is provided a method of manufacturing a multi-layer type coreless substrate, including: (I) preparing a carrier substrate including an insulating plate having at least one copper foil disposed on one surface or both surfaces thereof; (II) forming a plurality of first pillars on one surface or both surfaces of the carrier substrate using a first dry film pattern; (III) thermo-compressing a first compression layer sequentially including a first insulating layer and a first metal foil to one surface or both surfaces of the carrier substrate; (IV) separating the carrier substrate; (V) removing a protruded portion of the first metal foil and laminating a plurality of other insulating layers in which other circuit layers and other pillars are sequentially disposed on one surface or both surface outside the first insulating layer on which the first pillar is exposed using the first metal foil as a seed layer; (VI) forming an outermost circuit layer on an outermost insulating layer of the other insulating layers; and (VII) forming a first surface treating film or a second surface treating film on the outermost circuit layer.

The step (II) may include: (II-1) forming the first dry film pattern on a copper foil using the copper foil of the carrier substrate as the seed layer; (II-2) plating copper on the first dry film pattern by a chemical copper plating method to form the plurality of first pillars; and (II-3) peeling off the first dry film pattern.

The step (V) may include: (V-1) performing a partial polishing process for removing a protruded portion of the first metal foil; (V-2) forming the other circuit layers by any one of an additive method using chemical copper plating, a semi-additive process (SAP) and a modified semi-additive process (MSAP) using the first metal foil as the seed layer; (V-3) forming other dry film patterns on the other circuit layers; (V-4) plating copper on the other dry film patterns by a chemical copper plating method to form the plurality of other pillars connected with the other circuit layers; (V-5) peeling off the other dry film patterns; and (V-6) thermo-compressing other compression layers on which other insulating layers and other metal foils are sequentially disposed to other circuit layers including the other pillars, wherein the steps (V-1) to (V-6) may be repeatedly performed.

In the step (V-1), an end-mill may be used.

### BRIEF DESCRIPTION OF THE DRAWINGS

The above and other objects, features and advantages of the present invention will be more clearly understood from the following detailed description taken in conjunction with the accompanying drawings, in which:

FIG. 1 is a cross-sectional view of a multi-layer type coreless substrate according to a first preferred embodiment of the present invention;

FIGS. 2A to 2O are cross-sectional views sequentially showing the processes of a method of manufacturing a multi-layer type coreless substrate according to the first preferred embodiment of the present invention;

FIGS. 3A to 3O are cross-sectional views sequentially showing the processes of a method of manufacturing a multi-layer type coreless substrate according to a second preferred embodiment of the present invention;

FIGS. 4A to 4D are cross-sectional views sequentially showing the processes of a method of manufacturing a multi-layer type coreless substrate according to a third preferred embodiment of the present invention; and

FIG. 5 is a cross-sectional view of a multi-layer type coreless substrate according to a fourth preferred embodiment of the present invention.

### DESCRIPTION OF THE PREFERRED EMBODIMENTS

The above and other objects, features and advantages of the present invention will be more clearly understood from preferred embodiments and the following detailed description taken in conjunction with the accompanying drawings. In the specification, in adding reference numerals to components throughout the drawings, it is to be noted that like reference numerals designate like components even though components are shown in different drawings. Further, when it is determined that the detailed description of the known art related to the present invention may obscure the gist of the present invention, the detailed description thereof will be omitted. In the description, the terms “first”, “second”, and so on are used to distinguish one element from another element, and the elements are not defined by the above terms.

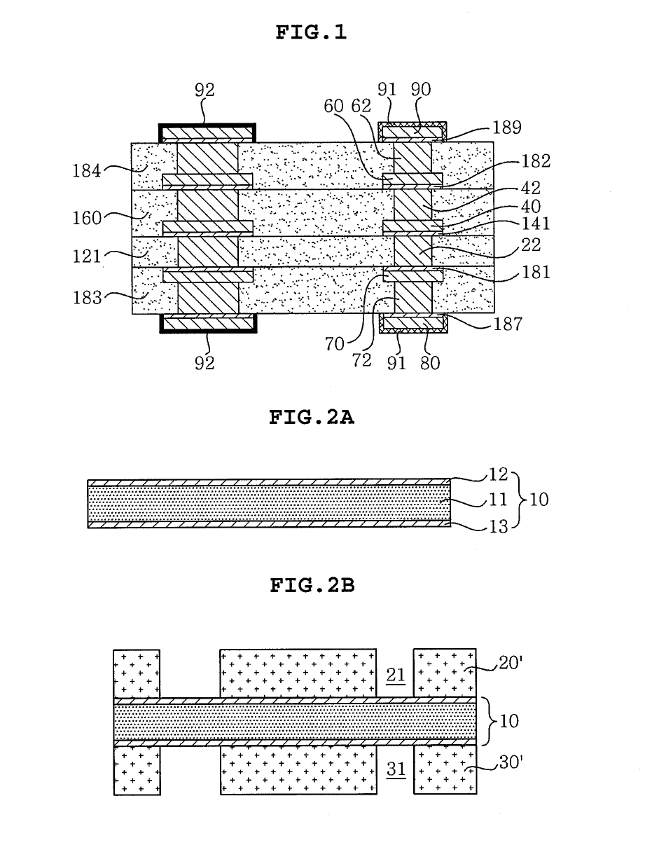

Hereinafter, preferred embodiments of the present invention will be described in detail with reference to the accompanying drawings. FIG. 1 is a cross-sectional view of a multi-layer type coreless substrate according to a first preferred embodiment of the present invention. Here, the multi-layer type coreless substrate according to the first preferred embodiment of the present invention will be described by applying a coreless substrate having, for example, four insulating layers. Further, the present invention may also be applied to the coreless substrate having a multi-layer structure including four or more insulating layers.

The multi-layer type coreless substrate according to the first preferred embodiment of the present invention includes a first insulating layer 121, an upper second insulating layer 160, an upper third insulating layer 184, and a lower second insulating layer 183, wherein an upper first circuit layer 40 and an upper second circuit layer 60 are each provided so as to be symmetrical with a lower first circuit layer 70 and a bottom circuit layer 80, based on the first insulating layer 121.

The multi-layer type coreless substrate according to the first preferred embodiment of the present invention includes a plurality of pillars 72, 22, 42, and 62 electrically connecting each circuit pattern from the bottom circuit layer 80 to a top circuit layer 90 and forms a first surface treating film 91 covering the bottom circuit layer 80 or the top circuit layer 90 so as to improve anti-oxidation and soldering of the bottom circuit layer 80 or the top circuit layer 90.

Further, the multi-layer type coreless substrate according to the first preferred embodiment of the present invention may further form a second surface treating film 92 on a part of the bottom circuit layer 80 or a part of the top circuit layer 90 so as to increase electric conductivity of the bottom circuit layer 80 or the top circuit layer 90, thereby improving connection reliability with external elements.

Therefore, the multi-layer type coreless substrate according to the first preferred embodiment of the present invention may include at least one insulating layer such as the first insulating layer 121 including only the first pillar 22 without including the circuit patterns and may be symmetrically provided with the plurality of circuit layers and the pillars in a vertical direction based on the insulating layer.

In detail, the plurality of circuit layers 40, 60, 70, 80, and 90 or the plurality of pillars 22, 42, 62, and 72 may be formed using a dry film pattern, for example, methods such as vapor deposition methods such as chemical vapor deposition (CVD), physical vapor deposition (PVD), and the like, a subtractive method, an additive method using electroless copper plating or electrolytic copper plating, and a semi-additive process (SAP), a modified semi-additive process (MSAP), and the like.

The first surface treating film 91 may be formed of any one of an organic solderability preservative (OSP) treating film, a black oxide film, and a brown oxide film, instead of a solder resist (SR). In particular, the OSP treating film is divided into an organic solvent type and a water soluble type, wherein the organic solvent type may be formed on a surface of the bottom circuit layer 80 or top circuit layer 90 using roll coating, spray coating, and the like, and the water soluble type may be formed by a dipping method.

Further, the second surface treating film 92 is formed of any one of, for example, a gold plating film, an electrolytic gold plating film, an electroless gold plating film, and an electroless nickel immersion gold (ENIG) film.

In particular, the ENIG film may be formed by plating nickel with an electroless plating process and then, plating immersion gold. The ENIG film has excellent heat resistance and solderability.

The first surface treating film 91 and the second surface treating film 92 are not limited to the above examples and may include hot air solder leveling (HASL) or other all the plating layers.

The multi-layer type coreless substrate according to the first preferred embodiment of the present invention may be easily provided with the buildup layer structure configured of the plurality of insulating layers and the plurality of pillars for electrically connecting the buildup layers by using a carrier and the dry film.

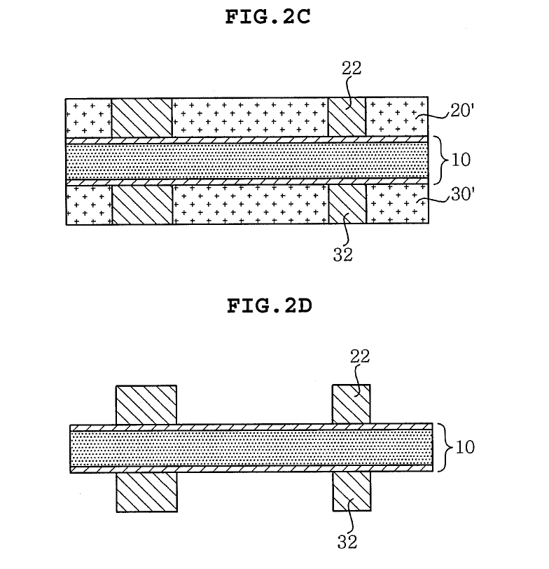

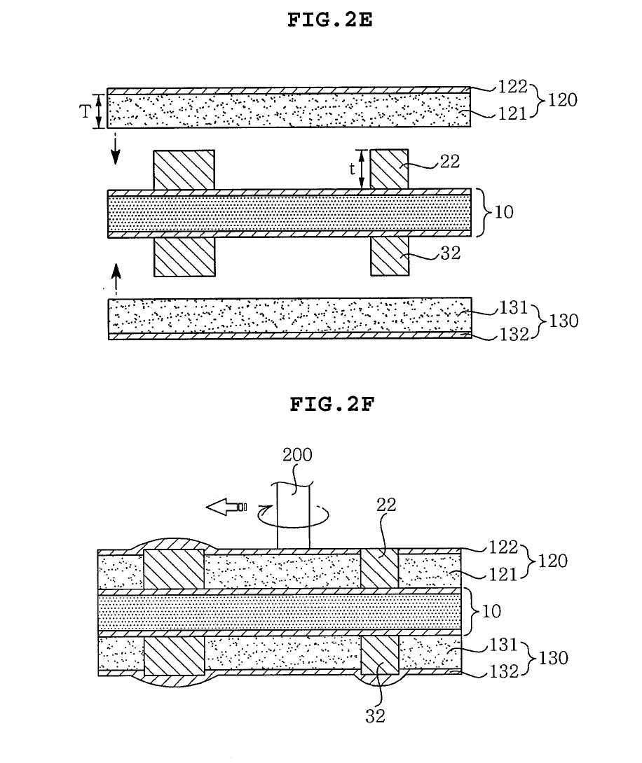

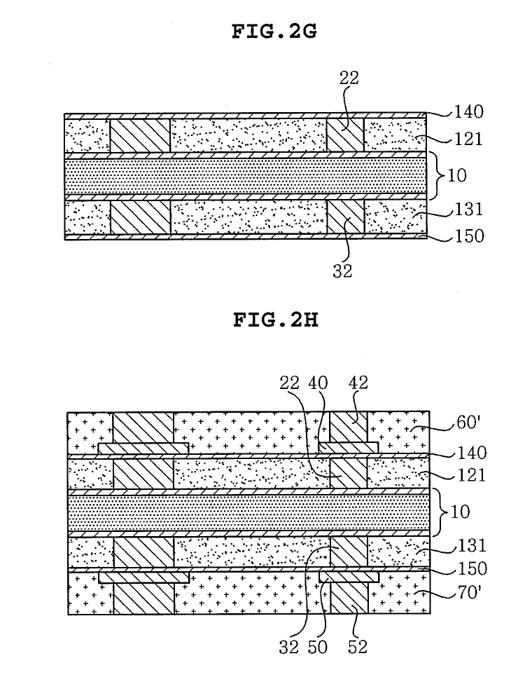

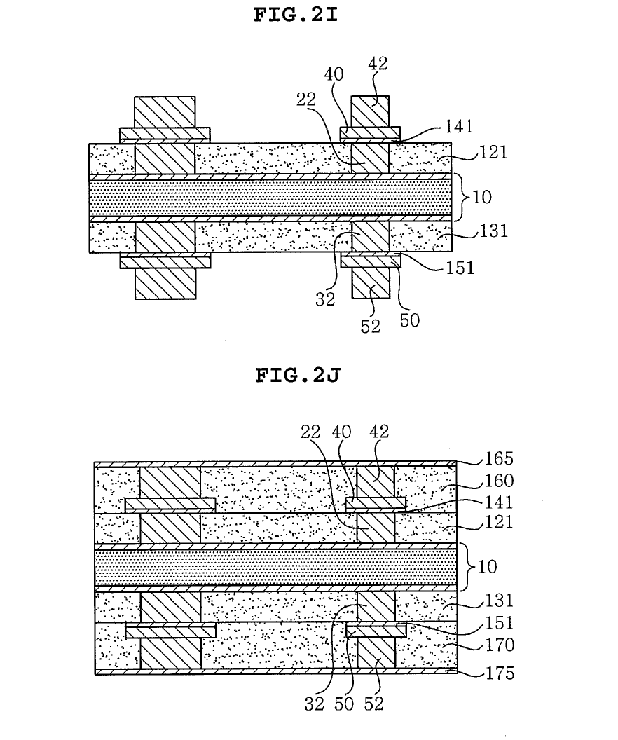

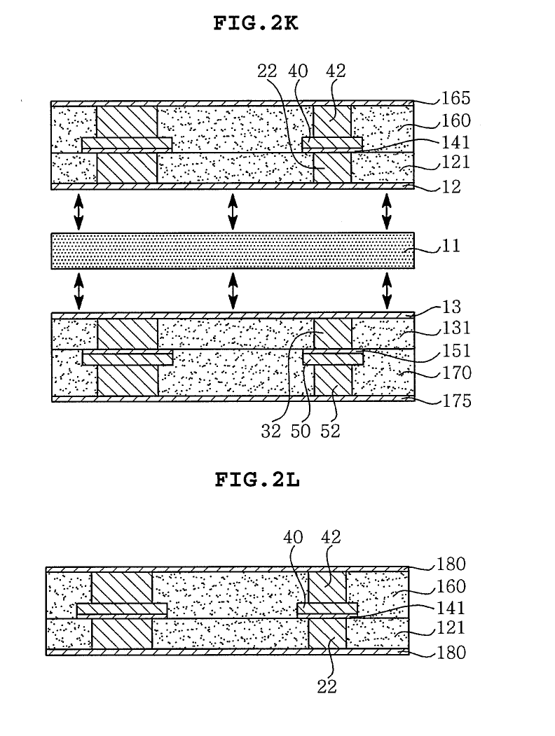

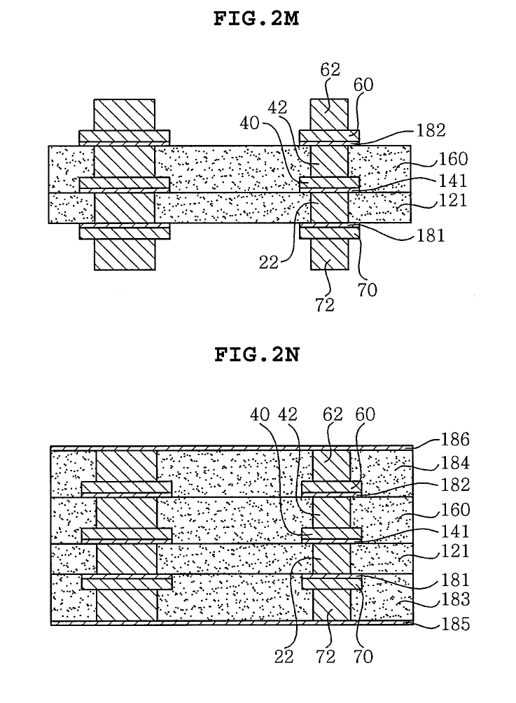

Hereinafter, the method of manufacturing a multi-layer type coreless substrate according to the first preferred embodiment of the present invention will be described with reference to FIGS. 2A to 2O. FIGS. 2A to 2O are cross-sectional views sequentially showing the process of a method of manufacturing a multi-layer type coreless substrate according to the first preferred embodiment of the present invention.

As illustrated in FIG. 2A, according to the method of manufacturing a multi-layer type coreless substrate according to the first preferred embodiment of the present invention, a carrier substrate 10 is first prepared.

The carrier substrate 10 has, for example, a structure in which the upper metal foil 12 and a lower metal foil 13 are laminated on both surfaces of the insulating plate 11 and serves to support the coreless substrate during the manufacturing process. Herein, the preferred embodiment of the present invention describes that the carrier substrate 10 has a structure that a metal foil is each disposed on both surfaces of the insulating plate 11, but is not limited thereto and the metal foil formed of two layers may each be disposed on both surfaces of the insulating plate 11 while having a thickness difference.

In detail, the insulating plate 11 of the carrier substrate 10 is made of a resin material, for example, thermosetting resin such as epoxy resin, thermoplastic resin such as polyimide, or a prepreg formed by impregnating stiffeners such as a glass fiber or an inorganic filler therein.

The upper metal foil 12 and the lower metal foil 13 are not particularly limited, but may be preferably made of high thermal conductivity and excellent rigidity.

After the carrier substrate 10 is prepared, as illustrated in FIG. 2B, first dry film patterns 20′ and 30′ having a plurality of opening parts 21 and 31 are formed on both surfaces of the carrier substrate 10.

In detail, in a process of forming the first dry film patterns 20′ and 30′, the dry films are laminated on both surfaces of the carrier substrate 10 by using a laminator.

Next, the dry film is optionally cured by an exposure process of exposing the dry film to light and melts only a portion which is not cured with a developer and may be patterned as the first upper dry film pattern 20′ having the upper opening part 21 and the first lower dry film pattern 30′ having the lower opening part 31, as illustrated in FIG. 2B.

After the first dry film patterns 20′ and 30′ having the plurality of opening parts 21 and 31, as illustrated in FIG. 2C, the upper opening part 21 and the lower opening part 31 are plated with copper by the electrolytic copper plating method to form the first pillar 22 and a first dummy pillar 32.

Next, the first dry film patterns 20′ and 30′ are peeled off by a stripping liquid and as illustrated in FIG. 2D, the first pillar 22 and the first dummy pillar 32 are disposed in plural on an upper surface and a lower surface of the carrier substrate 10. Here, an example of the stripping solution for removing the dry film patterns 20 and 30 may include alkali metal hydroxides, and the like.

After the first pillar 22 and the first dummy pillar 32 are disposed in plural on the upper surface and the lower surface of the carrier substrate 10, as illustrated in FIG. 2E, a first upper compression layer 120 and a first lower compression layer 130 are thermo-compressed on the upper surface and the lower surface of the carrier substrate 10.

In detail, the first upper compression layer 120 may be formed of a first insulating layer 121 on the upper surface of the carrier substrate 10 and a first metal foil 122 on the upper surface of the first insulating layer 121 and the first lower compression layer 130 may be formed of a first dummy insulating layer 131 on the lower surface of the carrier substrate 10 and a first dummy metal foil 132 on the lower surface of the first dummy insulating layer 131.

Here, the first metal foil 122 and the dummy metal foil 132 may be provided in, for example, a copper (Cu) foil form.

In this case, a thickness T of the first insulating layer 121 and the first dummy insulating layer 131 is formed to be smaller than a height t of the first pillar 22 and the first dummy pillar 32. For example, the height t of the first pillar 22 and the first dummy pillar 32 may be formed to be in a range of 1.1 to 2.0 times as much as the thickness T of the first insulating layer 121 and the first dummy insulating layer 131.

For this reason, when the height t of the first pillar 22 and the first dummy pillar 32 is formed so as to be 1.1 times smaller than the thickness T of the first insulating layer 121 and the first dummy insulating layer 131, the first pillar 22 and the first dummy pillar 32 are formed only within the compressed first insulating layer 121 and first dummy insulating layer 131 without penetrating therethrough.

On the other hand, when the height t of the first pillar 22 and the first dummy pillar 32 exceeds 2 times of the thickness T of the first insulating layer 121 and the first dummy insulating layer 131, after being compressed, the first pillar 22 and the first dummy pillar 32 may penetrate the first metal foil 122 and first dummy metal foil 132 or may damage them.

Therefore, the height t of the first pillar 22 and the first dummy pillar 32 may be formed to be in a range of 1.1 to 2.0 times as much as the thickness T of the first insulating layer 121 and the first dummy insulating layer 131.

As described above, the process of thermo-compressing the first upper compression layer 120 and the first lower compression layer 130 may use, for example, a thermo-compressing jig, and the like, to compress the first insulating layer 121 and the first dummy insulating layer 131 that are in a non-cured state on the upper surface and the lower surface of the carrier substrate 10, respectively.

When the first upper compression layer 120 and the first lower compression layer 130 are thermo-compressed, as illustrated in FIG. 2F, the first pillar 22 and the first dummy pillar 32 penetrate through the first insulating layer 121 and the first dummy insulating layer 131. Therefore, the first metal foil 122 and the first dummy metal foil 132 in the area corresponding to the first pillar 22 and the first dummy pillar 32 are protruded to the outside.

Next, a planarization process of removing protruded portions of the first metal foil 122 and the first dummy metal foil 132 and removing the first metal foil 122 and the first dummy metal foil 132 is performed.

In detail, the protruded portions of the first metal foil 122 and the first dummy metal foil 132 may be removed by a partial polishing using an end-mill 200 illustrated in FIG. 2F. Further, the process of removing the protruded portions of the first metal foil 122 and the first dummy metal foil 132 may use a polishing process using belt-sander, ceramic buff, and the like, or may also use a chemical mechanical polishing (CMP) process.

After the protruded portions of the first metal foil 122 and the first dummy metal foil 132 are removed, the first metal foil 122 and the first dummy metal foil 132 may be removed by performing the etching process, the polishing process, or the CMP process.

After the first metal foil 122 and the first dummy metal foil 132 are removed, as illustrated in FIG. 2G, a first seed layer 140 and a first dummy seed layer 150 are formed on the upper surface of the first insulating layer 121 on which the first pillar 22 is exposed and on the lower surface of the first dummy insulating layer 131 on which the first dummy pillar 32 is exposed, respectively.

Here, the first seed layer 140 and the first dummy seed layer 150 may be formed to have a two layer structure of a Ti layer/Cu layer by using chemical copper plating, in particular, electroless copper plating.

After the first seed layer 140 and the first dummy seed layer 150 are formed, as illustrated in FIG. 2H, the first circuit layer 40 and the first dummy circuit layer 50 are formed by using the methods such as SAP, MSAP, and the like.

Next, a second upper dry film pattern 60′ and a second lower dry film pattern 70′ are formed on the upper surface of the first seed layer 140 on which the first circuit layer 40 is formed and on the lower surface of the first dummy seed layer 150 on which the first dummy circuit layer 50 is formed, respectively. Here, the second upper dry film pattern 60′ and the second lower dry film pattern 70′ are each provided with a plurality of opening parts for forming the second pillar 42 and a second dummy pillar 52.

The second pillar 42 and the second dummy pillar 52 are formed by performing any one of the vapor deposition method such as CVD, PVD, and the like, the subtractive method, the additive method using electroless copper plating and electrolytic copper plating, and the methods such as SAP, MSAP, and the like, on the second upper dry film pattern 60′ and the second lower dry film pattern 70′.

In this case, the remaining portion other than the first seed layer 140 of the lower portion of the first circuit layer 40 by performing the patterning on the first seed layer 140 is removed by the etching to have a structure in which a surface on which the first insulating layer 121 is exposed is sequentially laminated with a first seed pattern 141, the first circuit layer 40, and the second pillar 42 as illustrated in FIG. 21.

Similarly, the methods are identically applied to the first dummy seed layer 150 to have a structure in which the first dummy seed pattern 151, the first dummy circuit layer 50, and the second dummy pillar 52 are sequentially laminated from the surface on which the first dummy insulating layer 131 is exposed.

Similarly to the process of using the first compression layers 120 and 130 for the first insulating layer 121 including the second pillar 42 and the first dummy insulating layer 131 including the second dummy pillar 52, the second upper compression layer configured of the second insulating layer 160 and a second metal foil 165 and the second lower compression layer configured of a second dummy insulating layer 170 and a second dummy metal foil 175 are thermo-compressed to the first insulating layer 121 and the first dummy insulating layer 131, respectively.

Here, the second metal foil 165 and the second dummy metal foil 175 may be provided in a copper (Cu) foil form, similar to the first metal foil 122 and the first dummy metal foil 132.

Therefore, as illustrated in FIG. 2J, the second pillar 42 and the second dummy pillar 52 each penetrate through the second insulating layer 160 and the second dummy insulating layer 170 to contact the second metal foil 165 and the second dummy metal foil 175.

In this case, the height of the second pillar 42 and the second dummy pillar 52 may be formed to have a range of 1.1 to 2.0 times as much as the thickness of the second insulating layer 160 and the second dummy insulating layer 170, similar to the feature of the height t of the first pillar 22 and the first dummy pillar 32.

Therefore, the second metal foil 165 and the second dummy metal foil 175 in the area corresponding to the second pillar 42 and the second dummy pillar 52 are protruded (not illustrated) to the outside.

Here, the protruded portions of the second metal foil 165 and the second dummy metal foil 175 may be removed by the partial polishing using the end-mill 200, similar to the protruded portions of the foregoing first metal foil 122 and first dummy metal foil 132. Further, the process of removing the protruded portions of the second metal foil 165 and the second dummy metal foil 175 may also use the polishing process using belt-sander, ceramic buff, and the like, or the CMP process.

After the protruded portions of the second metal foil 165 and the second dummy metal foil 175 are removed, routing is performed on the carrier substrate 10 in the state in which the second metal foil 165 and the second dummy metal foil 175 illustrated in FIG. 2J are not removed to separate the upper coreless printed circuit structure including the upper metal foil 12 from the lower coreless printed circuit structure including the lower metal foil 13 based on the insulating plate 11, as illustrated in FIG. 2K.

As such, the plurality of insulating layers including each pillar are laminated on the upper coreless printed circuit structure and the lower coreless printed circuit structure, respectively, that are separated from each other, thereby manufacturing the coreless substrate having the multi-layer structure.

For describing the process, the subsequent process will be described with reference to the upper coreless printed circuit structure including the second pillar 42. Further, the subsequent process to be described below may be identically applied to the lower coreless printed circuit structure including the second dummy pillar 52.

As illustrated in FIG. 21, the planarization process of removing the upper metal foil 12 and the second metal foil 165 for the separated upper coreless printed circuit structure is performed and then, the second seed layers 180 are disposed on the lower surface of the first insulating layer 121 on which the first pillar 22 is exposed and the upper surface of the second insulating layer 160 on which the second pillar 42 is exposed, respectively.

Here, the planarization process of removing the upper metal foil 12 and the second metal foil 165 may use the etching process, the polishing process, or the CMP process.

Further, similarly to the method of forming the first seed layer 140, the method of forming the second seed layer 180 may perform the chemical copper plating, in particular, the electroless copper plating, to form the two layer structure of, for example, a Ti layer/Cu layer.

Similarly to the process of forming the second seed layer 180 and then, forming the first circuit layer 40, the second circuit layer 60 and the second dummy circuit layer 70 are formed by the methods such as the SAP, the MSAP, and the like, as illustrated in FIG. 2M.

Next, any one of the methods such as the vapor deposition methods such as CVD, PVD, and the like, the subtractive method, the additive method using the electroless copper plating or the electrolytic copper plating, and the methods such as the SAP, the MSAP, and the like, is applied to the dry film pattern to form the third pillar 62 and the third dummy pillar 72.

In this case, the remaining portion other than the second seed layer 180 of the lower portion of the second circuit layer 60 by performing the patterning on the second seed layer 180 is removed by the etching to have a structure in which the surface on which the second insulating layer 160 is exposed is sequentially laminated with a second seed pattern 182, the second upper circuit layer 60, and the third pillar 62 as illustrated in FIG. 2M.

Similarly, the method is identically applied to the lower portion of the first insulating layer 121 to have the structure in which the second dummy seed pattern 181, the second dummy circuit layer 70, and the third dummy pillar 72 are sequentially laminated from the lower surface on which the first insulating layer 121 is exposed.

Next, similarly to the foregoing process of using the first compression layers 120 and 130, a third upper compression layer configured of a third insulating layer 184 and a third metal foil 186 and a third lower compression layer configured of a third dummy insulating layer 183 and a third dummy metal foil 185 are thermo-compressed to the second insulating layer 160 including the third pillar 62 and the first insulating layer 121 including the third dummy pillar 72, respectively.

Therefore, as illustrated in FIG. 2N, the third pillar 62 and the third dummy pillar 72 each penetrate through the third insulating layer 184 and the third dummy insulating layer 183 to contact the third metal foil 186 and the third dummy metal foil 185.

In this case, the height of the third pillar 62 and the third dummy pillar 72 may be formed to have a range of 1.1 to 2.0 times as much as the thickness of the third insulating layer 184 and the third dummy insulating layer 183, similar to the feature of the height t of the first pillar 22 and the first dummy pillar 32.

Therefore, the third metal foil 186 and the third dummy metal foil 185 in the area corresponding to the third pillar 62 and the third dummy pillar 72 are protruded (not illustrated) to the outside.

In this case, the partial polishing process of removing the protruded portions of the third metal foil 186 and the third dummy metal foil 185 by using the end-mill may be performed and the planarization process of removing the third metal foil 186 and the third dummy metal foil 185 may be performed.

Thereafter, the outer surface of the third insulating layer 184 and the outer surface of the third dummy insulating layer 183 are subjected to the chemical copper plating, in particular, the electroless copper plating, thereby forming the third seed layer.

Next, as illustrated in FIG. 20, the outer surface of the third insulating layer 184 and the outer surface of the third dummy insulating layer 183 may be each provided with a third seed pattern 189, the top circuit layer 90, a third dummy seed pattern 187, and the bottom circuit layer 80. Similarly to the method of forming the second upper circuit layer 60, a method of forming the top circuit layer 90 and the bottom circuit layer 80 uses the methods such as the SAP, the MSAP, and the like.

Next, the first surface treating film 91 or the second surface treating film 92 are formed on the third seed pattern 189 and the top circuit layer 90 and the third dummy seed pattern 187 and the bottom circuit layer 80.

The first surface treating film 91 may be formed of any one of the OSP treating film, the black oxide film, and the brown oxide film, instead of the SR. Here, the OSP treating film is divided into an organic solvent type and a water soluble type, wherein the organic solvent type may be formed on the surface of the bottom circuit layer 80 or the top circuit layer 90 using roll coating, spray coating, and the like, and the water soluble type may be formed by the dipping method. Further, the black oxide film or the brown oxide film may be formed by oxidizing the top circuit layer 90 and the bottom circuit layer 80 that are made of copper.

The second surface treating film 92 is formed of any one of, for example, a gold plating film, an electrolytic gold plating film, an electroless gold plating film, and an electroless nickel immersion gold (ENIG) film. In particular, the ENIG film may be formed by plating nickel with an electroless plating process and then, plating immersion gold.

Further, the first surface treating film 91 and the second surface treating film 92 are not limited to the above examples and may be formed as hot air solder leveling (HASL) or other all the surface treating layers.

According to the first preferred embodiments of the present invention, the method of manufacturing a multi-layer type coreless substrate can easily manufacture the coreless substrate including five circuit layers electrically connected by the plurality of pillars using the carrier substrate 10 and the dry film pattern, thereby resolving the problems of the machining time and the manufacturing costs occurring while forming the vias using a laser according to the prior art.

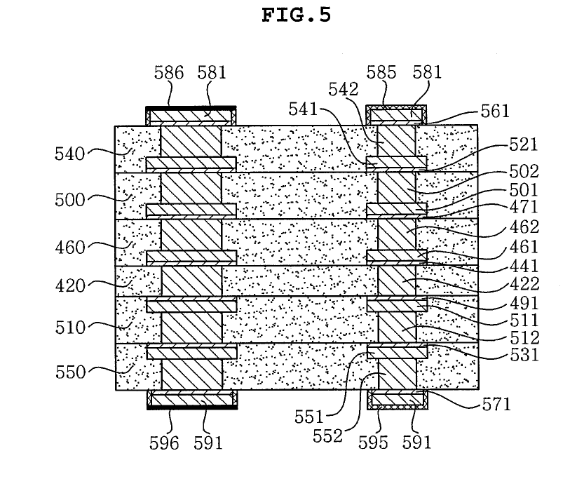

Further, the multi-layer type coreless substrate according to the first preferred embodiment of the present invention has the insulating layer including the seed patterns, the circuit layers, and the pillars further formed on both surfaces thereof, thereby manufacturing the multi-layer type coreless substrate having seven circuit layers 581, 541, 501, 461, 511, 551, and 591 as illustrated in FIG. 5.

Therefore, like a multi-layer type coreless substrate according to a fourth preferred embodiment of the present invention illustrated in FIG. 5, the insulating layers including the seed patterns, the circuit layers, and the pillars are each laminated in plural on the outside thereof by repeatedly performing the method of manufacturing the multi-layer type coreless substrate according to the first preferred embodiment of the present invention, thereby implementing the multi layers.

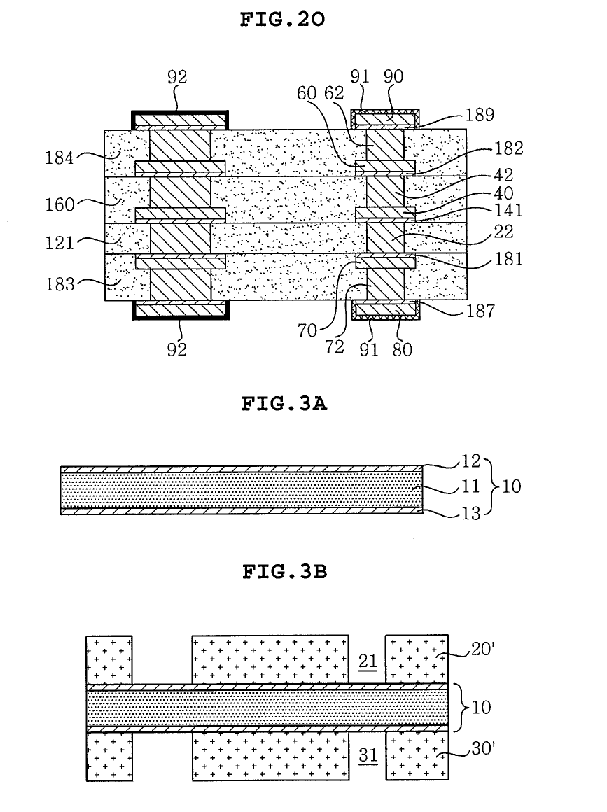

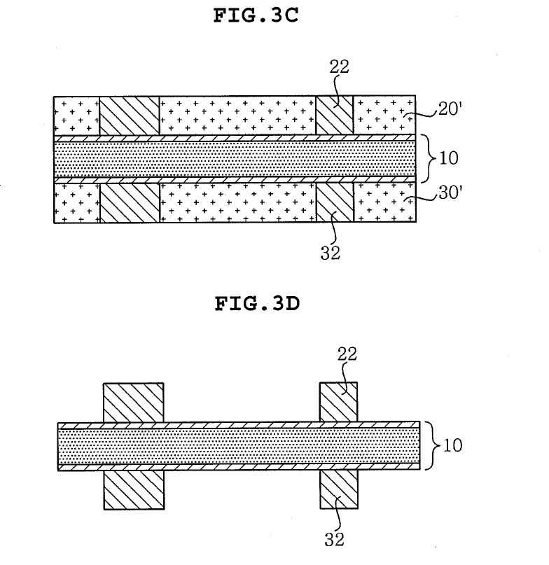

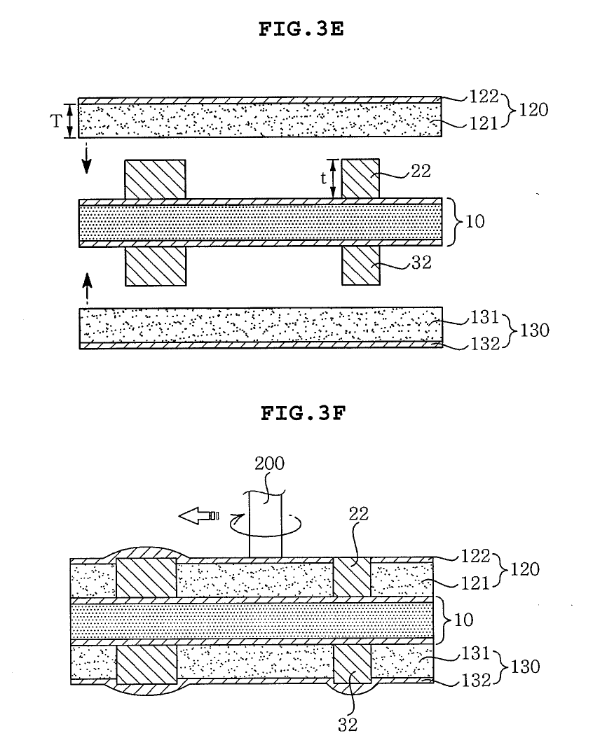

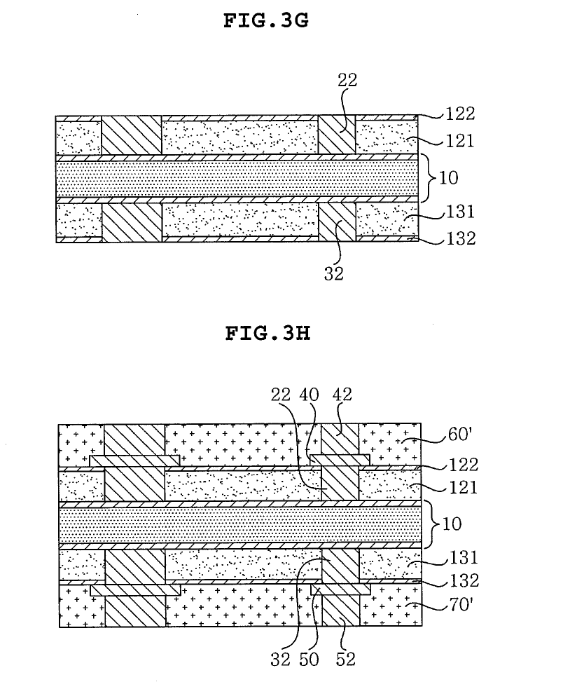

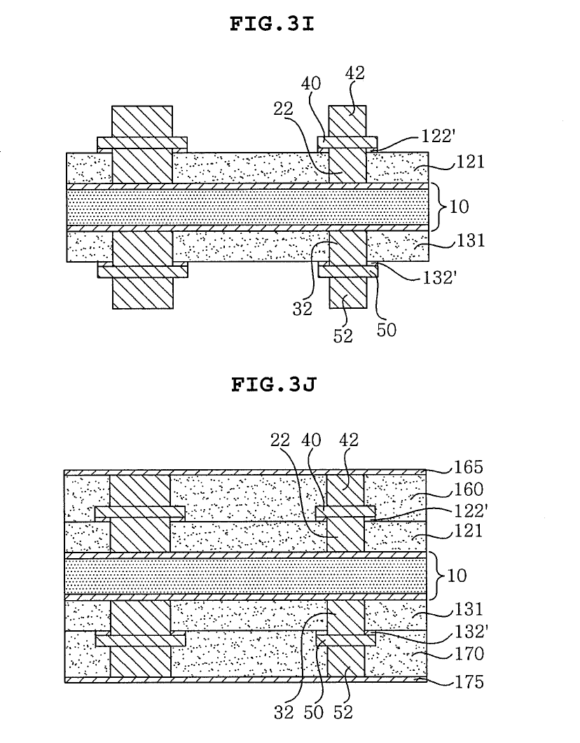

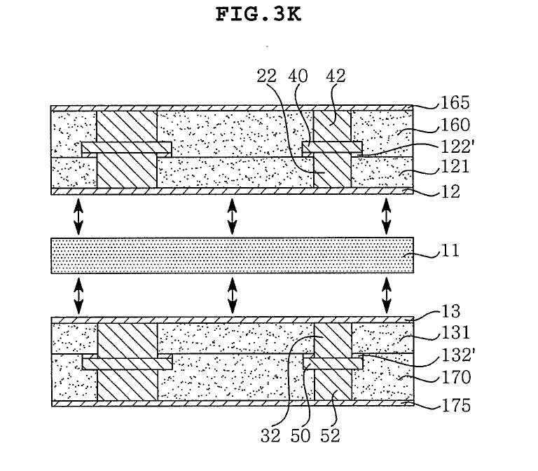

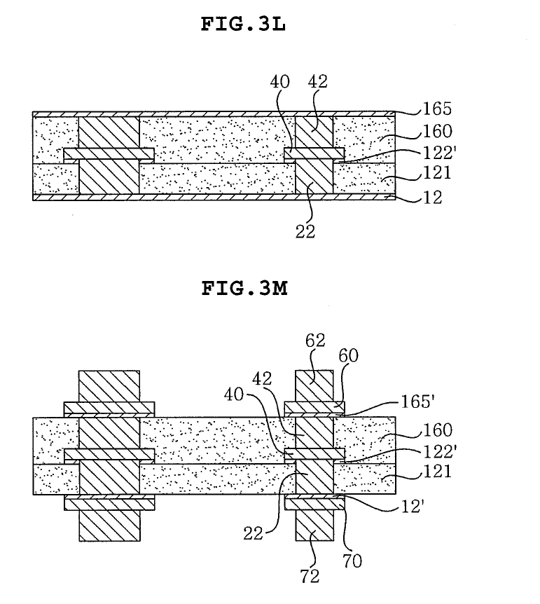

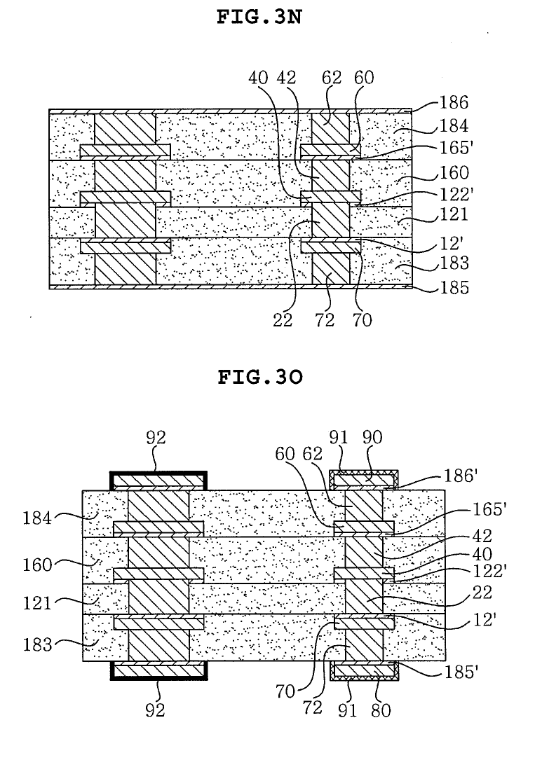

Hereinafter, a method of manufacturing a multi-layer type coreless substrate according to a second preferred embodiment of the present invention will be described with reference to FIGS. 3A to 30. FIGS. 3A to 30 are cross-sectional views sequentially showing the process of a method of manufacturing a multi-layer type coreless substrate according to the second preferred embodiment of the present invention.

As illustrated in FIG. 3A, according to the method of manufacturing a multi-layer type coreless substrate according to the second preferred embodiment of the present invention, a carrier substrate 10 is first prepared.

The carrier substrate 10 has, for example, a structure in which the upper metal foil 12 and a lower metal foil 13 are laminated on both surfaces of the insulating plate 11 and serves to support the coreless substrate during the manufacturing process. Herein, the preferred embodiment of the present invention describes that the carrier substrate 10 has a structure that a metal foil is each disposed on both surfaces of the insulating plate 11, but is not limited thereto and the metal foil formed of two layers may each be disposed on both surfaces of the insulating plate 11 while having a thickness difference.

In detail, the insulating plate 11 of the carrier substrate 10 is made of, for example, thermosetting resin such as epoxy resin, thermoplastic resin such as polyimide, as resin materials or prepreg in which stiffeners such as glass fiber or inorganic filler are impregnated therein.

The upper metal foil 12 and the lower metal foil 13 are not particularly limited, but may be preferably made of high thermal conductivity and excellent rigidity.

After the carrier substrate 10 is prepared, as illustrated in FIG. 3B, first dry film patterns 20′ and 30′ having a plurality of opening parts 21 and 31 are formed on both surfaces of the carrier substrate 10.

In detail, in a process of forming the first dry film patterns 20′ and 30′, the dry films are laminated on both surfaces of the carrier substrate 10 by using a laminator.

Next, the dry film is optionally cured by an exposure process of exposing the dry film to light and melts only a portion which is not cured with a developer and may be patterned as the first upper dry film pattern 20′ having the upper opening part 21 and the first lower dry film pattern 30′ having the lower opening part 31, as illustrated in FIG. 3B.

After the first dry film patterns 20′ and 30′ having the plurality of opening parts 21 and 31 are formed, as illustrated in FIG. 3 C, the upper opening part 21 and the lower opening part 31 are plated with copper by the electrolytic copper plating method to form the first pillar 22 and a first dummy pillar 32.

Next, the first dry film patterns 20′ and 30′ are peeled off by a stripping liquid and as illustrated in FIG. 3D, the first pillar 22 and the first dummy pillar 32 are disposed in plural on the upper surface and the lower surface of the carrier substrate 10. Here, an example of the stripping solution for removing the dry film patterns 20 and 30 may include alkali metal hydroxides, and the like.

After the first pillar 22 and the first dummy pillar 32 are disposed in plural on the upper surface and the lower surface of the carrier substrate 10, as illustrated in FIG. 3E, the first upper compression layer 120 and the first lower compression layer 130 are thermo-compressed on the upper surface and the lower surface of the carrier substrate 10.

In detail, the first upper compression layer 120 may be formed of a first insulating layer 121 on the upper surface of the carrier substrate 10 and the first metal foil 122 on upper surface of the first insulating layer 121 and the first lower compression layer 130 may be formed of a first dummy insulating layer 131 on the lower surface of the carrier substrate 10 and the first dummy metal foil 132 on the lower surface of the first dummy insulating layer 131.

Here, the first metal foil 122 and the first dummy metal foil 132 may be provided in, for example, a copper (Cu) foil form.

In this case, the thickness T of the first insulating layer 121 and the first dummy insulating layer 131 is formed to be smaller than the height t of the first pillar 22 and the first dummy pillar 32. For example, the height t of the first pillar 22 and the first dummy pillar 32 may be formed to be in a range of 1.1 to 2.0 times as much as the thickness T of the first insulating layer 121 and the first dummy insulating layer 131.

For this reason, when the height t of the first pillar 22 and the first dummy pillar 32 is formed so as to be 1.1 times smaller than the thickness T of the first insulating layer 121 and the first dummy insulating layer 131, the first pillar 22 and the first dummy pillar 32 are formed only within the compressed first insulating layer 121 and first dummy insulating layer 131 without penetrating therethrough.

On the other hand, when the height t of the first pillar 22 and the first dummy pillar 32 exceeds 2 times of the thickness T of the first insulating layer 121 and the first dummy insulating layer 131, the first pillar 22 and the first dummy insulating layer 32 may penetrate the compressed first metal foil 122 and first dummy metal foil 132 or may damage them.

Therefore, the height t of the first pillar 22 and the first dummy pillar 32 may be formed to be in a range of 1.1 to 2.0 times as much as the thickness T of the first insulating layer 121 and the first dummy insulating layer 131.

As described above, the process of thermo-compressing the first upper compression layer 120 and the first lower compression layer 130 may use, for example, a thermo-compressing jig, and the like, to compress the first insulating layer 121 and the first dummy insulating layer 131 that are in a non-cured state on the upper surface and the lower surface of the carrier substrate 10, respectively.

When the first upper compression layer 120 and the first lower compression layer 130 are thermo-compressed, as illustrated in FIG. 3F, the first pillar 22 and the first dummy pillar 32 penetrate through the first insulating layer 121 and the first dummy insulating layer 131. Therefore, the first metal foil 122 and the first dummy metal foil 132 in the area corresponding to the first pillar 22 and the first dummy pillar 32 are protruded to the outside.

Next, the partial polishing process of removing the protruded portions of the first metal foil 122 and the first dummy metal foil 132 are performed.

In detail, the protruded portions of the first metal foil 122 and the first dummy metal foil 132 may be removed by the partial polishing using an end-mill 200. Further, the process of removing the protruded portions of the first metal foil 122 and the first dummy metal foil 132 may also use the polishing process using the belt-sander, ceramic buff, and the like, or the CMP process.

When the protruded portions of the first metal foil 122 and the first dummy metal foil 132 are removed, as illustrated in FIG. 3G, the first metal foil 122 and the first dummy metal foil 132 are provided and the first metal foil 122 and the first dummy metal foil 132 may be used as the seed layer.

The first circuit layer 40 and the first dummy circuit layer 50 are formed by the methods such as the SAP, the MSAP, and the like by using the first metal foil 122 and the first dummy metal foil 132.

Next, as illustrated in FIG. 3H, a second upper dry film pattern 60′ and a second lower dry film pattern 70′ are formed on the upper surface of the first seed layer 140 on which the first circuit layer 40 is formed and on the lower surface of the first dummy seed layer 150 on which the first dummy circuit layer 50 is formed, respectively. Here, the second upper dry film pattern 60′ and the second lower dry film pattern 70′ are each provided with a plurality of opening parts for forming the second pillar 42 and a second dummy pillar 52.

The second pillar 42 and the second dummy pillar 52 are formed by performing any one of the vapor deposition method such as CVD, PVD, and the like, the subtractive method, the additive method using electroless copper plating and electrolytic copper plating, and the methods such as SAP, MSAP, and the like, on the second upper dry film pattern 60′ and the second lower dry film pattern 70′.

In this case, the remaining portion other than the first metal foil 122 of the lower portion of the first circuit layer 40 by performing the patterning on the metal foil 122 is removed by the etching to have a structure in which a surface on which the first insulating layer 121 is exposed is sequentially laminated with the first metal foil pattern 122′, the first circuit layer 40, and the second pillar 42 as illustrated in FIG. 31.

Similarly, the methods are identically applied to the first dummy metal foil 132 to have a structure in which the first dummy metal foil pattern 132′, the first dummy circuit layer 50, and the second dummy pillar 52 are sequentially laminated from the surface on which the first dummy insulating layer 131 is exposed.

Similarly to the process of using the first compression layers 120 and 130 for the first insulating layer 121 including the second pillar 42 and the first dummy insulating layer 131 including the second dummy pillar 52, the second upper compression layer configured of the second insulating layer 160 and a second metal foil 165 and the second lower compression layer configured of a second dummy insulating layer 170 and a second dummy metal foil 175 are thermo-compressed to the first insulating layer 121 and the first dummy insulating layer 131, respectively.

Here, the second metal foil 165 and the second dummy metal foil 175 may be provided in a copper (Cu) foil form, similar to the first metal foil 122 and the first dummy metal foil 132.

Therefore, as illustrated in FIG. 3J, the second pillar 42 and the second dummy pillar 52 each penetrate through the second insulating layer 160 and the second dummy insulating layer 170 to contact the second metal foil 165 and the second dummy metal foil 175.

In this case, the height of the second pillar 42 and the second dummy pillar 52 may be formed to have a range of 1.1 to 2.0 times as much as the thickness of the second insulating layer 160 and the second dummy insulating layer 170, similar to the feature of the height t of the first pillar 22 and the first dummy pillar 32.

Therefore, the second metal foil 165 and the second dummy metal foil 175 in the area corresponding to the second pillar 42 and the second dummy pillar 52 are protruded (not illustrated) to the outside.

Here, the protruded portions of the second metal foil 165 and the second dummy metal foil 175 may be removed by the partial polishing using the end-mill 200, similar to the protruded portions of the foregoing first metal foil 122 and first dummy metal foil 132. Further, the process of removing the protruded portions of the second metal foil 165 and the second dummy metal foil 175 may also use the polishing process using belt-sander, ceramic buff, and the like, or the CMP process.

After the protruded portions of the second metal foil 165 and the second dummy metal foil 175 are removed, routing is performed on the carrier substrate 10 in the state in which the second metal foil 165 and the second dummy metal foil 175 illustrated in FIG. 3J are not removed to separate the upper coreless printed circuit structure including the upper metal foil 12 from the lower coreless printed circuit structure including the lower metal foil 13 based on the insulating plate 11, as illustrated in FIG. 3K.

As such, the plurality of insulating layers including each pillar are laminated on the upper coreless printed circuit structure and the lower coreless printed circuit structure, respectively, that are separated from each other, thereby manufacturing the coreless substrate having the multi-layer structure.

For describing the process, the subsequent process will be described with reference to the upper coreless printed circuit structure including the second pillar 42. Further, the subsequent process to be described below may be identically applied to the lower coreless printed circuit structure including the second dummy pillar 52.

As illustrated in FIG. 31, the subsequent process is performed on the separated upper coreless printed circuit structure by using the upper metal foil 12 and the second metal foil 165 as the seed layer.

Next, similarly to the process of forming the first circuit layer 40 and the second pillar 42, the second circuit layer 60 and the third pillar 62 are formed on a second metal foil pattern 165′ and the second dummy circuit layer 70 and the third dummy pillar 72 are formed on the upper metal foil pattern 12′, by the methods such as the SAP, the MSAP, and the like, as illustrated in FIG. 3M.

Next, similarly to the foregoing process of using the first compression layers 120 and 130, the third compression layer configured of a third insulating layer 184 and a third metal foil 186 and the third lower compression layer configured of the third dummy insulating layer 183 and the third dummy metal foil 185 are thermo-compressed to the second insulating layer 160 including the third pillar 62 and the first insulating layer 121 including the third dummy pillar 72, respectively.

Therefore, as illustrated in FIG. 3n, the third pillar 62 and the third dummy pillar 72 each penetrate through the third insulating layer 184 and the third dummy insulating layer 183 to contact the third metal foil 186 and the third dummy metal foil 185.

In this case, the height of the third pillar 62 and the third dummy pillar 72 may be formed to have a range of 1.1 to 2.0 times as much as the thickness of the third insulating layer 184 and the third dummy insulating layer 183, similar to the feature of the height t of the first pillar 22 and the first dummy pillar 32.

Therefore, the third metal foil 186 and the third dummy metal foil 185 in the area corresponding to the third pillar 62 and the third dummy pillar 72 are protruded (not illustrated) to the outside.

In this case, the partial polishing process of removing the protruded portions of the third metal foil 186 and the third dummy metal foil 185 by using the end-mill may be performed.

The third metal foil 186 and the third dummy metal foil 185 are used as the seed layer like the foregoing upper metal foil 12 and second metal foil 165.

As illustrated in FIG. 20, the third metal foil pattern 186′ and the top circuit layer 90 are formed on the outer surface of the third insulating layer 184 and the third dummy metal foil pattern 185′ and the bottom circuit layer 80 may be formed on the lower surface of the third dummy insulating layer 183, by using the third metal foil 186 and the third dummy metal foil 185 as the seed layer.

Similarly to the method of forming the second upper circuit layer 60, a method of forming the top circuit layer 90 and the bottom circuit layer 80 uses the methods such as the SAP, the MSAP, and the like.

Next, the first surface treating film 91 or the second surface treating film 92 are formed on the third seed pattern 189 and the top circuit layer 90 and the third dummy seed pattern 187 and the bottom circuit layer 80.

The first surface treating film 91 may be formed of any one of the OSP treating film, the black oxide film, and the brown oxide film, instead of the SR. Here, the OSP treating film is divided into an organic solvent type and a water soluble type, wherein the organic solvent type may be formed on the surface of the bottom circuit layer 80 or the top circuit layer 90 using roll coating, spray coating, and the like, and the water soluble type may be formed by the dipping method. Further, the black oxide film or the brown oxide film may be formed by oxidizing the top circuit layer 90 and the bottom circuit layer 80 that are made of copper.

The second surface treating film 92 is formed of any one of, for example, a gold plating film, an electrolytic gold plating film, an electroless gold plating film, and an electroless nickel immersion gold (ENIG) film. In particular, the ENIG film may be formed by plating nickel with an electroless plating process and then, plating immersion gold.

Further, the first surface treating film 91 and the second surface treating film 92 are not limited to the above examples and may be formed as hot air solder leveling (HASL) or other all the surface treating layers.

The method of manufacturing a multi-layer coreless substrate according to the second preferred embodiment of the present invention can easily form the circuit layer by using the applied copper foil as the seed layer without forming the separate seed layer.

Therefore, the method of manufacturing a multi-layer type coreless substrate according to the second preferred embodiment of the present invention can save the manufacturing costs and reduce the manufacturing time without the process of forming the separate seed layer.

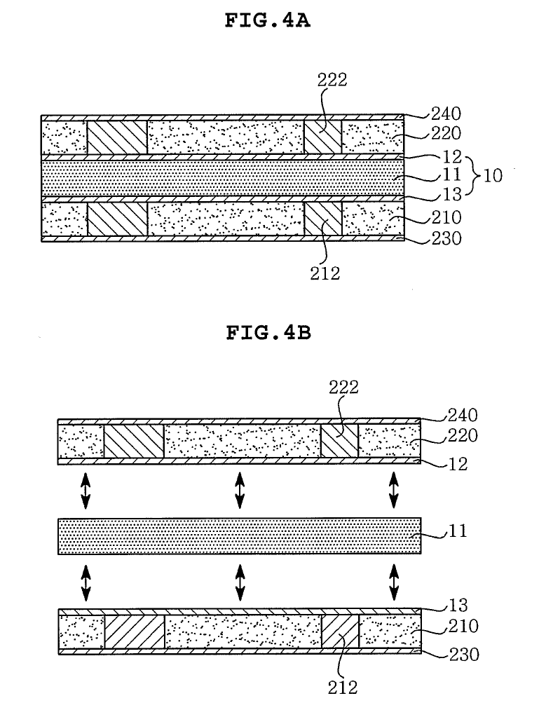

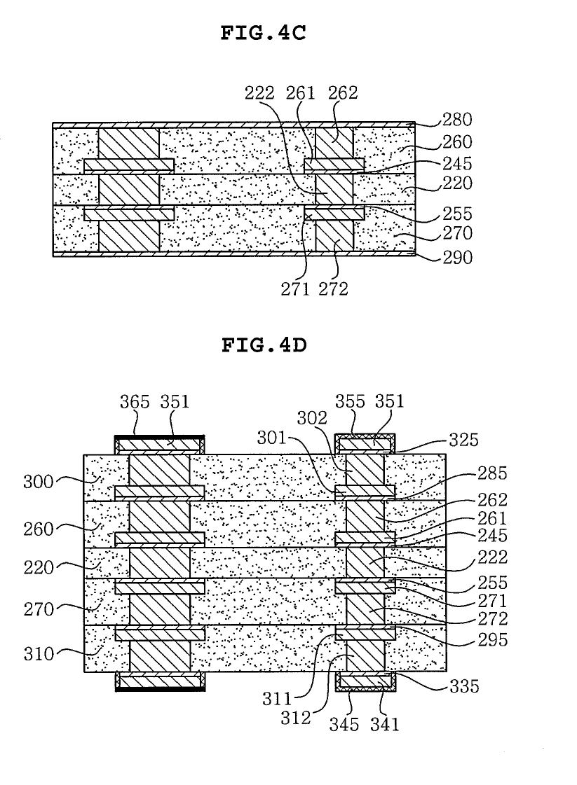

Hereinafter, a method of manufacturing a multi-layer type coreless substrate according to a third preferred embodiment of the present invention will be described with reference to FIGS. 4A to 4D. FIGS. 4A to 4D are cross-sectional views sequentially showing the process of a method of manufacturing a multi-layer type coreless substrate according to a third preferred embodiment of the present invention. Here, the method of manufacturing a multi-layer type coreless substrate according to the third preferred embodiment of the present invention will be described with reference to a method of manufacturing a multi-layer type coreless substrate having even numbers of circuit layers such as six circuit layers 351, 301, 261, 271, 311, and 341. Therefore, the method of manufacturing a multi-layer type coreless substrate according to the third preferred embodiment of the present invention will be described by omitting similar components to the method of manufacturing a multi-layer type coreless substrate according to the first preferred embodiment of the present invention.

The method of manufacturing a multi-layer type coreless substrate according to the third preferred embodiment of the present invention first thermo-compresses the first upper compression layer and the first lower compression layer to the carrier substrate 10 including the plurality of first pillars 222 and the first dummy pillars 212 formed on the upper and lower surfaces thereof as illustrated in FIG. 4A, such that the first pillar 222 contacts a first metal support layer 240 and the first dummy pillar 212 contacts the first dummy metal support layer 230.

Next, the routing is performed on the carrier substrate 10 to separate the upper coreless printed circuit structure including the upper metal foil 12 and the lower coreless printed circuit structure including the lower metal foil 13 based on the insulating plate 11 as illustrated in FIG. 4B.

As described above, the separated upper coreless printed circuit structure and lower coreless printed circuit structure each use the precursor having the insulating layer structure having only the pillar disposed therein without the circuit layer, thereby manufacturing the multi-layer type coreless substrate having even numbers of circuit layers.

Next, the planarization process of removing the upper metal foil 12 and the first metal support layer 240 is performed on the upper coreless printed circuit structure and then, the first upper seed pattern 245 and the first upper circuit layer 261 and the first lower seed pattern 255 and the first lower circuit layer 271 are symmetrically formed on both surfaces of the first pillar 222, based on the first insulating layer 220 having the first pillar 222 exposed on both surfaces thereof by the subsequent process Further, the same process may be performed on the lower coreless printed circuit structure.

The dry film patterns are formed on the first upper circuit layer 261 and the first lower circuit layer 271 and the second upper pillar 262 and the second lower pillar 272 are each formed by applying any one of the vapor deposition method such as CVD, PVD, and the like, the subtractive method, the additive method using the electroless copper plating or the electrolytic copper plating, the methods such as SAP, MSAP, and the like, to the dry film pattern.

Next, as illustrated in FIG. 4C, the second upper compression layer configured of the second insulating layer 260 and the second metal support layer 280 and the second lower compression layer configured of the second dummy insulating layer 270 and the second dummy metal support layer 290 are thermo-compressed to the second upper pillar 262 and the second lower pillar 272, respectively.

Next, the planarization process of removing the second metal support layer 280 and the second dummy metal support layer 290 is performed and as illustrated in FIG. 4D, the second seed pattern 285 and the second upper circuit layer 301 and the second dummy seed pattern 295 and the second lower circuit layer 311 may be formed on the upper surface of the second insulating layer 260 and the lower surface of the second dummy insulating layer 270, respectively, as illustrated in FIG. 4D.

When the process is repeatedly performed, as illustrated in FIG. 4D, other insulating layers different from the six circuit layers 351, 301, 261, 271, 311, and 341 may be symmetrically formed based on the first insulating layer 220.

According to the preferred embodiments of the present invention, the multi-layer type coreless substrate can easily include the buildup layer structure configured of the plurality of insulating layers and the plurality of pillars for electrically connecting the buildup layers.

According to the preferred embodiments of the present invention, the method of manufacturing a multi-layer type coreless substrate can easily manufacture the coreless substrate including the plurality of circuit layers electrically connected by the plurality of pillars using the carrier substrate and the dry film pattern, thereby resolving the problems of the machining time and the manufacturing costs occurring while forming the vias using a laser according to the prior art.

Although the embodiments of the present invention have been disclosed for illustrative purposes, it will be appreciated that the present invention is not limited thereto, and those skilled in the art will appreciate that various modifications, additions and substitutions are possible, without departing from the scope and spirit of the invention.

Accordingly, any and all modifications, variations or equivalent arrangements should be considered to be within the scope of the invention, and the detailed scope of the invention will be disclosed by the accompanying claims.

What is claimed is:

1. A multi-layer type coreless substrate, comprising:
a first insulating layer including at least one first pillar;
a plurality of insulating layers laminated on one surface or both surfaces of the first insulating layer, each including at least one circuit layer and at least another pillar connected to the circuit layer; and
a plurality of outermost circuit layers contacting a pillar disposed on an outermost insulating layer of the plurality of insulating layers.

2. The multi-layer type coreless substrate as set forth in claim 1, wherein the circuit layers symmetrically contact each other on both surfaces thereof, based on the first pillar, and
the pillars each connected with the circuit layers symmetrically contacting each other are symmetrically provided based on the first pillar.

3. The multi-layer type coreless substrate as set forth in claim 1, wherein the outermost circuit layer is provided with a first surface treating film or a second surface treating layer.

4. The multi-layer type coreless substrate as set forth in claim 1, wherein the circuit layers and other pillars are sequentially disposed repeatedly, by including the circuit layer contacting the first pillar and the pillar connected to the circuit layer.

5. The multi-layer type coreless substrate as set forth in claim 3, wherein the first surface treating film is formed of any one of an organic solderability preservative (OSP) treating film, a black oxide film, and a brown oxide film, instead of a solder resist (SR).

6. The multi-layer type coreless substrate as set forth in claim 3, wherein the second surface treating film is formed of any one of a gold plating film, an electrolytic gold plating film, an electroless gold plating film, and an electroless nickel immersion gold (ENIG) film.

7. A method of manufacturing a multi-layer type coreless substrate, the method comprising:
(A) preparing a carrier substrate including an insulating plate having at least one copper foil disposed on one surface or both surfaces thereof;
(B) forming a plurality of first pillars on one surface or both surfaces of the carrier substrate using a first dry film pattern;
(C) thermo-compressing a first compression layer sequentially including a first insulating layer and a first metal foil to one surface or both surfaces of the carrier substrate;
(D) removing a protruded portion of the first metal foil and forming a circuit layer on an outer surface of a first insulating layer on which the first pillar is exposed;
(E) forming a plurality of second pillars connected with the circuit layer using a second dry film pattern disposed on the outer surface of the first insulating layer;
(F) thermo-compressing a second compression layer sequentially including a second insulating layer and a second metal foil to the outer surface of the first insulating layer on which the second pillar is disposed;
(E) separating the carrier substrate; and
(H) removing a protruded portion of the second metal foil and laminating a plurality of other insulating layers on which other circuit layers and other pillars are sequentially disposed on an outer surface of the second insulating layer on which the second pillar is exposed or the outer surface of the first insulating layer on which the first pillar is exposed.

8. The method as set forth in claim 7, further comprising:
(I) forming an outermost circuit layer on an outermost insulating layer of the other insulating layers; and
(J) forming a first surface treating film or a second surface treating film on the outermost circuit layer.

9. The method as set forth in claim 7, wherein the step (B) includes:
(B-1) forming a seed layer on one surface or both surfaces of the carrier substrate;
(B-2) forming the first dry film pattern on the seed layer;
(B-3) plating copper on the first dry film pattern by a chemical copper plating method; and
(B-4) peeling off the first dry film pattern.

10. The method as set forth in claim 7, wherein in the step (C), the first insulating layer in a non-cured state is thermo-compressed to the first pillar using a thermo-compression jig.

11. The method as set forth in claim 7, wherein in the step (C), a height t of the first pillar is formed in a range of 1.1 to 2.0 times as much as a thickness T of the first insulating layer.

12. The method as set forth in claim 7, wherein the step (D) includes:
(D-1) performing a partial polishing process for removing a protruded portion of the first metal foil;
(D-2) forming a seed layer on the outer surface of the first insulating layer on which the first pillar is exposed; and
(D-3) forming the circuit layer by performing any one of an additive method using chemical copper plating, a semi-additive process (SAP) and a modified semi-additive process (MSAP) on the seed layer.

13. The method as set forth in claim 12, wherein in the step (D-1), the partial polishing process uses an end-mill.

14. The method as set forth in claim 7, wherein the step (E) includes:
(E-1) forming a seed layer on the outer surface of the first insulating layer;
(E-2) forming a second dry film pattern on the seed layer;
(E-3) plating copper on the second dry film pattern by a chemical copper plating method to form the second pillar; and
(E-4) peeling off the second dry film pattern.

15. The method as set forth in claim 7, wherein in the step (F), the second insulating layer in a non-cured state is thermo-compressed to the second pillar using a thermo-compression jig.

16. The method as set forth in claim 7, wherein the step (H) includes:
(H-1) performing a partial polishing process for removing a protruded portion of the second metal foil;
(H-2) forming another seed layer on the outer surface of the second insulating layer on which the second pillar is exposed or the outer surface of the first insulating layer on which the first pillar is exposed;
(H-3) forming the other circuit layers by performing any one of an additive method using chemical copper plating, a semi-additive process (SAP) and a modified semi-additive process (MSAP) on another seed layer;
(H-4) forming other dry film patterns on the other circuit layers;
(H-5) plating copper on the other dry film patterns by a chemical copper plating method to form the plurality of other pillars connected with the other circuit layers;
(H-6) peeling off the other dry film patterns; and
(H-7) thermo-compressing other compression layers on which the other insulating layers and the other metal foils are sequentially disposed to other seed layers including the other pillars, and
the steps (H-1) to (H-7) are repeatedly performed.

17. The method as set forth in claim 8, wherein the first surface treating film is formed of any one of an organic solderability preservative (OSP) treating film, a black oxide film, and a brown oxide film, instead of a solder resist (SR), and
the second surface treating film is formed of any one of a gold plating film, an electrolytic gold plating film, an electroless gold plating film, and an electroless nickel immersion gold (ENIG) film.

18. A method of manufacturing a multi-layer type coreless substrate, the method comprising:
(I) preparing a carrier substrate including an insulating plate having at least one copper foil disposed on one surface or both surfaces thereof;
(II) forming a plurality of first pillars on one surface or both surfaces of the carrier substrate using a first dry film pattern;
(III) thermo-compressing a first compression layer sequentially including a first insulating layer and a first metal foil to one surface or both surfaces of the carrier substrate;
(IV) separating the carrier substrate;
(V) removing a protruded portion of the first metal foil and laminating a plurality of other insulating layers in which other circuit layers and other pillars are sequentially disposed on one surface or both surface outside the first insulating layer on which the first pillar is exposed using the first metal foil as a seed layer;
(VI) forming an outermost circuit layer on an outermost insulating layer of the other insulating layers; and
(VII) forming a first surface treating film or a second surface treating film on the outermost circuit layer.

19. The method as set forth in claim 18, wherein the step (II) includes:
(II-1) forming the first dry film pattern on a copper foil using the copper foil of the carrier substrate as the seed layer;
(II-2) plating copper on the first dry film pattern by a chemical copper plating method to form the plurality of first pillars; and
(II-3) peeling off the first dry film pattern.

20. The method as set forth in claim 18, wherein in the step (III), the first insulating layer in a non-cured state is thermo-compressed to the first pillar using a thermo-compression jig.

21. The method as set forth in claim 18, wherein in the step (III), a height t of the first pillar is formed in a range of 1.1 to 2.0 times as much as a thickness T of the first insulating layer.

22. The method as set forth in claim 18, wherein the step (V) includes:
(V-1) performing a partial polishing process for removing a protruded portion of the first metal foil;
(V-2) forming the other circuit layers by any one of an additive method using chemical copper plating, a semi-additive process (SAP) and a modified semi-additive process (MSAP) using the first metal foil as the seed layer;
(V-3) forming other dry film patterns on the other circuit layers;
(V-4) plating copper on the other dry film patterns by a chemical copper plating method to form the plurality of other pillars connected with the other circuit layers;
(V-5) peeling off the other dry film patterns; and
(V-6) thermo-compressing other compression layers on which other insulating layers and other metal foils are sequentially disposed to other circuit layers including the other pillars, and
the steps (V-1) to (V-6) are repeatedly performed.

23. The method as set forth in claim 22, wherein in the step (V-1), an end-mill is used.
